(19) United States
(12) Patent Application Publication
(10) Pub. No.: US 2026/0271772 A1
(43) Pub. Date: Sep. 10, 2026

(54) SEMICONDUCTOR PACKAGES AND METHODS OF FORMING

(71) Applicant: Taiwan Semiconductor Manufacturing Co., Ltd., Hsinchu (TW)

(72) Inventors: Chi-Yang Yu, Zhongli (TW); Jung Wei Cheng, Hsinchu (TW); Chao-Wen Shih, Zhubei (TW); Shang-Yun Hou, Jubei (TW); Ying-Ching Shih, Hsinchu (TW); Li-Hui Cheng, New Taipei (TW)

(21) Appl. No.: 19/263,366

(22) Filed: Jul. 8, 2025

Related U.S. Application Data
(60) Provisional application No. 63/769,359, filed on Mar. 10, 2025.

(51) Int. Cl. H01L 23/31; H01L 21/48; H01L 21/56; H01L 23/00; H01L 23/367; H01L 25/16

(52) U.S. Cl. CPC H10W 74/121; H10W 40/228; H10W 70/023; H10W 74/016; H10W 74/15; H10W 90/00; H10W 90/724; H10W 90/734

(57) ABSTRACT

A semiconductor package includes a substrate and a semiconductor structure attached to the substrate, where the semiconductor structure includes: an interposer; a die attached to a first side of the interposer distal from the substrate; a first encapsulant material on the first side of the interposer around the die; and conductive bumps at a second side of the interposer facing the substrate. The semiconductor package further includes: a second encapsulant material on the substrate around the semiconductor structure, where there is a cavity in the second encapsulant material over the semiconductor structure, wherein a first side of the semiconductor structure distal from the substrate is exposed at a bottom of the cavity; a thermal interface material (TIM) in the cavity and attached to the first side of the semiconductor structure; and a heat spreader over and attached to the TIM.

### PRIORITY CLAIM AND CROSS-REFERENCE

This application claims priority to U.S. Provisional Patent Application No. 63/769,359, filed Mar. 10, 2025, entitled “Semiconductor Package Molding,” which application is hereby incorporated by reference in its entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. Another example is a Chip-On-Wafer-On-Substrate (CoWoS) structure, where a semiconductor chip is attached to a wafer (e.g., an interposer) to form a Chip-On-Wafer (CoW) structure. The CoW structure is then attached to a substrate (e.g., a printed circuit board) to form a CoWoS structure. These and other advanced packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor structure, in accordance with an embodiment.

FIGS. 2, 3A, 3B, 4, 5A, and 5B illustrate cross-sectional views of a semiconductor package at various stages of manufacturing, in accordance with an embodiment.

FIG. 6 illustrates a cross-sectional view of a vapor chamber, in accordance with an embodiment.

FIG. 7 illustrates a cross-sectional view of a semiconductor package, in accordance with another embodiment.

FIG. 8 illustrates a cross-sectional view of a semiconductor package, in accordance with another embodiment.

FIGS. 9A and 9B illustrate cross-sectional views of a semiconductor package, in accordance with another embodiment.

FIG. 10 illustrates a cross-sectional view of a semiconductor package, in accordance with another embodiment.

FIG. 11 illustrates a cross-sectional view of a semiconductor package, in accordance with yet another embodiment.

FIG. 12 illustrates a flow chart of a method of forming a semiconductor package, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. Throughout the description, unless otherwise specified, like reference numerals in difference figures refer to the same or similar component formed by a same or similar formation method using a same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a semiconductor package is formed by bonding a semiconductor structure (e.g., a CoW structure) to a substrate, and forming a molding material on the substrate around the semiconductor structure. A portion of the molding material over the semiconductor structure is then removed to form a cavity in the molding material. The upper surface of the semiconductor package is exposed at the bottom of the cavity. Next, a thermal interface material (TIM) (e.g., a metal TIM, or a liquid metal TIM) is formed on the upper surface of the semiconductor package. A heat spreader is then attached to the TIM. In an embodiment, a gap is formed between the TIM and a sidewall of the molding material exposed to the cavity. In addition, a trench may be formed in a lower surface of the heat spreader facing the semiconductor package. The trench is directly over the gap after the heat spreader is attached to the TIM. The gap in the molding material and the trench in the heat spreader could trap the molten metal material of the TIM during manufacturing or operation of the semiconductor package. The disclosed semiconductor packages achieve improved heat dissipation efficiency, less warpage, and higher manufacturing throughput.

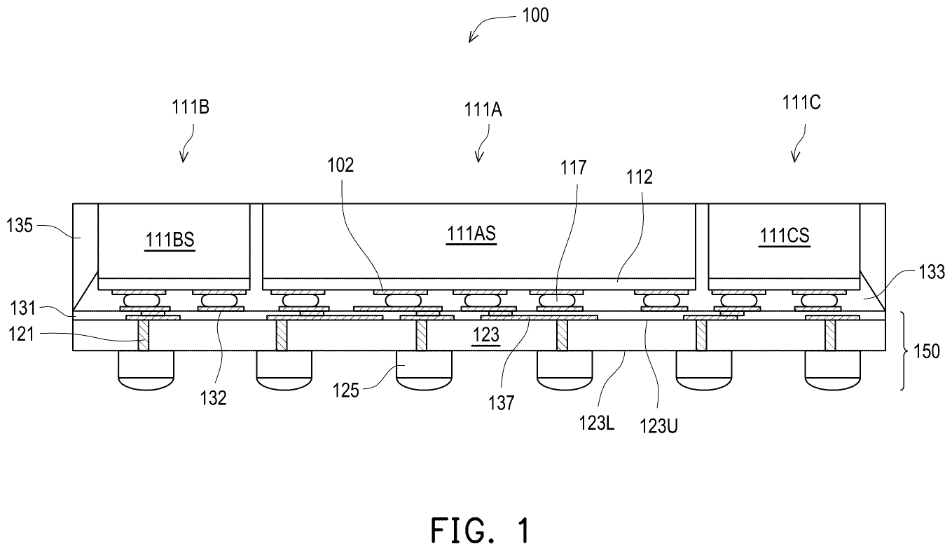

FIG. 1 illustrates a cross-sectional view of a semiconductor structure 100, in accordance with an embodiment. The semiconductor structure 100 may also be referred to as a Chip-on-Wafer (CoW) structure, or a CoW package. As illustrated in FIG. 1, the semiconductor structure 100 includes a wafer 150 (e.g., an interposer), one or more dies 111 (e.g., 111A, 111B, and 111C) attached to the wafer 150, an underfill material 133 between the dies 111 and the wafer 150, and a molding material 135 over the wafer 150 and around the dies 111. The semiconductor structure 100 is subsequently attached to a substrate to form a semiconductor package 200 having a Chip-On-Wafer-On-Substrate (CoWoS) structure, details of which are described hereinafter.

To form the semiconductor structure 100, one or more dies 111 (may also be referred to as semiconductor dies, chips, or integrated circuit (IC) dies) are attached to an upper surface of the wafer 150. In the illustrated embodiment, the wafer 150 is an interposer, and therefore, the wafer 150 may also be referred to as an interposer in the discussion herein, with the understanding that other types of suitable wafers may also be used as the wafer 150. The dies 111 (e.g., 111A, 111B, and 111C) are a same type of dies (e.g., memory dies, or logic dies), in some embodiments. In other embodiments, the dies 111 are of different types, e.g., the die 111A may be a logic die and the dies 111B and 111C may be memory dies. The number of dies 111 and the relative locations of the dies 111 in FIG. 1 are merely examples, other numbers and other locations of the dies are possible and are fully intended to be included within the scope of the present disclosure.

In some embodiments, the die 111A includes a substrate 111AS, electrical components (e.g., transistors, resistors, capacitors, diodes, or the like) formed in/on the substrate 111AS, and an interconnect structure 112 over the substrate 111AS connecting the electrical components to form functional circuits of the die 111A. The die 111A also includes conductive pads 102 and conductive pillars 117 (also referred to as die connectors) formed on the conductive pads 102. The conductive pillars 117 provide electrical connection to the circuits of the die 111A. Note that in the description herein, unless otherwise specified, “conductive” refers to electrically conductive (e.g., instead of thermally conductive), and the term “thermally conductive” is used explicitly to describe thermal conductivity.

The substrate 111AS of the die 111A may be a semiconductor substrate, doped or undoped, or an active layer of a silicon-on-insulator (SOI) substrate. The semiconductor substrate may include semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The electrical components of the die 111A comprise a wide variety of active components (e.g., transistors) and passive components (e.g., capacitors, resistors, inductors), and the like. The electrical components of the die 111A may be formed using any suitable methods either within or on the substrate 111AS of the die 111A. The interconnect structure 112 of the die 111A comprises one or more metallization layers (e.g., copper layers) formed in one or more dielectric layers, and is used to connect the various electrical components to form functional circuitry. In an embodiment the interconnect structure is formed of alternating layers of dielectric and conductive material (e.g., copper) and may be formed through any suitable process (such as deposition, damascene, dual damascene, etc.).

One or more passivation layers (not shown) may be formed over the interconnect structure 112 of the die 111A in order to provide a degree of protection for the underlying structures of the die 111A. The passivation layer may be made of one or more suitable dielectric materials such as silicon oxide, silicon nitride, low-k dielectrics such as carbon doped oxides, extremely low-k dielectrics such as porous carbon doped silicon dioxide, combinations of these, or the like. The passivation layer may be formed through a process such as chemical vapor deposition (CVD), although any suitable process may be utilized.

Conductive pads 102 may be formed over the passivation layer and may extend through the passivation layer to be in electrical contact with the interconnect structure 112 of the die 111A. The conductive pads 102 may comprise aluminum, but other materials, such as copper, may alternatively be used.

Conductive pillars 117 of the die 111A are formed on the conductive pads 102 to provide conductive regions for electrical connection to the circuits of the die 111A. The conductive pillars 117 may be copper pillars, contact bumps such as microbumps, or the like, and may comprise a material such as copper, tin, silver, combinations thereof, or other suitable material.

The dies 111B and 111C are formed using the same or similar processing steps, although different electrical components and different electrical connections may be formed such that circuits with different functions are formed for the different dies. Details are not repeated here.

Looking at the wafer 150, which includes a substrate 123, through vias 121 (also referred to as through-substrate vias (TSVs)), a redistribution structure 131, conductive pads 132 at an upper surface of the wafer 150, and external connectors 125 (may also be referred to as conductive bumps) at a lower surface of the wafer 150. The structure of the wafer 150 in FIG. 1 is merely a non-limiting example. Other structures are possible and are fully intended to be included within the scope of the present disclosure.

The substrate 123 may be, e.g., a silicon substrate, doped or undoped, or an active layer of a silicon-on-insulator (SOI) substrate. However, the substrate 123 may alternatively be a glass substrate, a ceramic substrate, a polymer substrate, or any other substrate that may provide a suitable protection and/or interconnection functionality.

In some embodiments, the substrate 123 may include electrical components, such as resistors, capacitors, signal distribution circuitry, combinations of these, or the like. These electrical components may be active, passive, or a combination thereof. In other embodiments, the substrate 123 is free from both active and passive electrical components therein. All such combinations are fully intended to be included within the scope of this disclosure.

Through vias 121 are formed in the substrate 123 and extend from an upper surface 123U of the substrate 123 to a lower surface 123L of the substrate 123. The through vias 121 provide electrical connections between the conductive pads 132 and the external connectors 125. The through vias 121 may be formed of a suitable conductive material such as copper, tungsten, aluminum, alloys, doped polysilicon, combinations thereof, or the like. A barrier layer may be formed between the through vias 121 and the substrate 123. The barrier layer may comprise a suitable material such as titanium nitride, although other materials, such as tantalum nitride, titanium, or the like, may alternatively be utilized.

Once the through vias 121 have been formed, the redistribution structure 131 may be formed on the upper surface 123U of the substrate 123 in order to provide interconnectivity between the through vias 121, the external connectors 125, and the dies 111A, 111B and 111C. The redistribution structure 131 comprises electrically conductive features (conducive lines and/or vias) disposed in one or more dielectric layers of the redistribution structure 131. In some embodiments, the one or more dielectric layers are formed of a polymer, such as polybenzoxazole (PBO), polyimide, benzocyclobutene (BCB), or the like. In other embodiments, the dielectric layer is formed of a nitride such as silicon nitride; an oxide such as silicon oxide, phosphosilicate glass (PSG), borosilicate glass (BSG), boron-doped phosphosilicate glass (BPSG), or the like; or the like. The one or more dielectric layers of the redistribution structure 131 may be formed by any acceptable deposition process, such as spin coating, chemical vapor deposition (CVD), laminating, combination thereof, or the like.

In some embodiments, the conductive features of the redistribution structure 131 comprise conductive lines and/or conductive via formed of a suitable conductive material such as copper, titanium, tungsten, aluminum, or the like. The conductive features may be formed by, e.g., forming openings in a dielectric layer of the redistribution structure to expose underlying conductive features, forming a seed layer over the dielectric layer and in the openings, forming a patterned photoresist with a designed pattern over the seed layer, plating (e.g., electroplating or electroless plating) the conductive material in the designed pattern and over the seed layer, and removing the photoresist and portions of seed layer on which the conductive material is not formed. After the redistribution structure 131 is formed, the conductive pads 132 may be formed over and electrically coupled to the redistribution structure 131 using any suitable material such as copper, aluminum, gold, tungsten, combinations thereof, or the like.

Next, the external connectors 125 are formed on the lower surface 123L of the substrate 123. The external connectors 125 may be any suitable type of external contacts, such as microbumps, copper pillars, a copper layer, a nickel layer, a lead free (LF) layer, an electroless nickel electroless palladium immersion gold (ENEPIG) layer, a Cu/LF layer, a Sn/Ag layer, a Sn/Pb, combinations thereof, or the like.

Besides the example discussed above, other structures and/or materials for the interposer 150 are also possible and are fully intended to be included within the scope of the present disclosure. For example, the substrate 123 of the interposer 150 may include multiple layers of a polymer material. Conductive features are formed in the layers of polymer material. The redistribution structure 131 is formed over the layers of polymer material. In some embodiments, one or more local silicon interconnect (LSI) chips are encapsulated in the layers of polymer material to offer high-density interconnection between the dies 111. The LSI chips may include a substrate (e.g., a silicon substrate) and conductive features formed in/on the substrate using, e.g., the back-end-of-line (BEOL) semiconductor manufacturing techniques, thus providing high-density interconnections not achievable by the formation method of the redistribution structure 131.

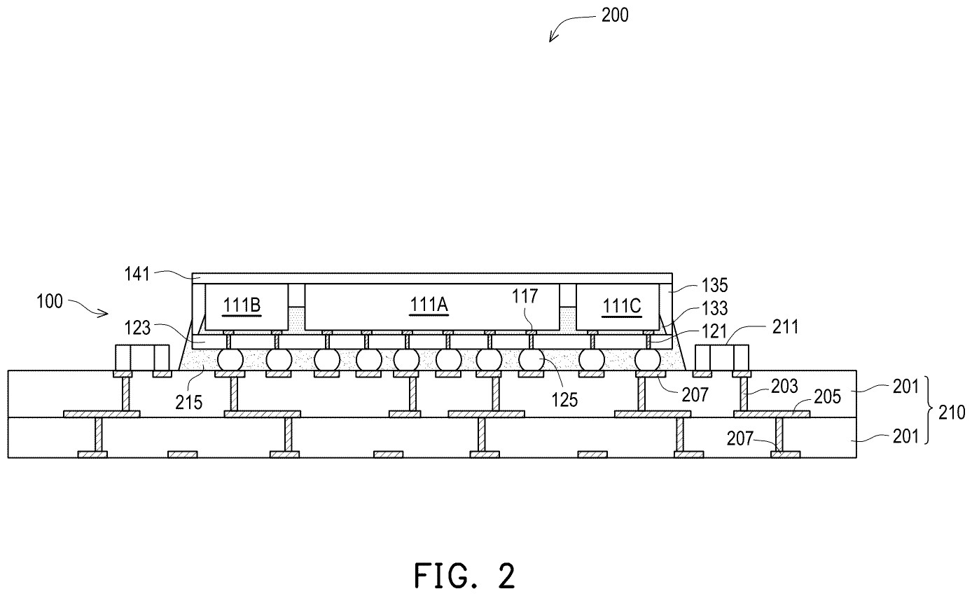

In the example of FIG. 1, the conductive pillar 117 of the dies 111 are bonded to the conductive pads 132 of the wafer 150 by, e.g., solder regions. A reflow process may be performed to bond the dies 111 to the wafer 150. After the dies 111 are bonded to the wafer 150, the underfill material 133 is formed between the dies 111 and the wafer 150. The underfill material 133 may, for example, comprise a liquid epoxy that is dispensed in a gap between the dies 111 and the wafer 150, e.g., using a dispensing needle or other suitable dispensing tool, and then cured to harden. As illustrated in FIG. 1, the underfill material 133 fills the gap between the dies 111 and the wafer 150, and may also fill gaps between sidewalls of the dies 111. The underfill material 133 between adjacent dies 111 may extend upwards along sidewalls of the dies 111 to the upper surfaces of the dies 111 distal from the wafer 150, as illustrated in FIG. 1, or may partially cover the sidewalls of the dies 111, as illustrated in FIG. 2.

Next, a molding material 135 (may also be referred to as an encapsulant material) is formed over the wafer 150 and around the dies 111. The molding material 135 also surrounds the underfill material 133. The molding material 135 may comprise an epoxy, an organic polymer, a polymer with or without a silica-based filler or glass filler added, or other materials, as examples. In some embodiments, the molding material 135 comprises a liquid molding compound (LMC) that is a gel type liquid when applied. The molding material 135 may also comprise a liquid or solid when applied. Alternatively, the molding material 135 may comprise other insulating and/or encapsulating materials. The molding material 135 is applied using a wafer level molding process in some embodiments. The molding material 135 may be molded using, for example, compressive molding, transfer molding, molded underfill (MUF), or other methods.

Next, the molding material 135 is cured using a curing process, in some embodiments. The curing process may comprise heating the molding material 135 to a predetermined temperature for a predetermined period of time, using an anneal process or other heating process. The curing process may also comprise an ultra-violet (UV) light exposure process, an infrared (IR) energy exposure process, combinations thereof, or a combination thereof with a heating process. Alternatively, the molding material 135 may be cured using other methods. In some embodiments, a curing process is not included.

After the molding material 135 is formed, a planarization process, such as chemical and mechanical planarization (CMP), may be performed to remove excess portions of the molding material 135 from over the dies 111, such that the molding material 135 and the dies 111 have a coplanar upper surface. As illustrated in FIG. 1, sidewalls of the molding material 135 are vertically aligned with respective sidewalls of the substrate 123.

The semiconductor structure 100 illustrated in FIG. 1 is used to form various semiconductor packages (e.g., 200, 200A, 200B, 200C, 200D, and 200E) in the discussion hereinafter. For simplicity, not all features of the semiconductor structure 100 are illustrated in subsequently figures, with the understanding that the semiconductor structure 100 in subsequent figures may include additional details/features, such as those illustrated in FIG. 1.

FIGS. 2, 3A, 3B, 4, 5A, and 5B illustrate cross-sectional views of a semiconductor package 200 at various stages of manufacturing, in accordance with an embodiment. As illustrated in FIG. 2, the semiconductor structure 100 of FIG. 1 is attached to (e.g., bonded to) an upper surface of a substrate 210 (e.g., a printed circuit board). The resulting structure may be referred to as a Chip-On-Wafer-On-Substrate (CoWoS) structure. FIG. 2 also illustrates passive components 211 attached to the upper surface of the substrate 210. The passive components 211 may be discrete electrical components, such as resistors, capacitors, inductors, or the like.

In some embodiments, the substrate 210 is a multiple-layer circuit board such as a printed circuit board (PCB). For example, the substrate 210 may include one or more dielectric layers 201 formed of bismaleimide triazine (BT) resin, FR-4 (a composite material composed of woven fiberglass cloth with an epoxy resin binder that is flame resistant), ceramic, glass, plastic, tape, film, or other supporting materials. The substrate 210 may include electrically conductive features (e.g., conductive lines 205 and vias 203) formed in/on the substrate 210. As illustrated in FIG. 2, the substrate 210 has conductive pads 207 formed at an upper surface of the substrate 210 and at a lower surface of the substrate 210. The conductive pads 207 are electrically coupled to the conductive features of the substrate 210.

The semiconductor structure 100 is bonded to the conductive pads 207 of the substrate 210. A reflow process may be performed to electrically and mechanically couple the external connectors 125 of the semiconductor structure 100 to the conductive pads 207 of the substrate 210.

FIG. 2 also illustrates passive components 211 attached to the upper surface of the substrate 210 adjacent to the semiconductor structure 100. The passive components 211 may be, e.g., surface-mount devices (SMDs) such as surface-mount capacitors, surface-mount inductors, surface-mount resistors, or the like. Contact terminals of the passive components 211 are bonded to respective conductive pads 207. The passive components 211 are attached to the substrate 210 before the semiconductor structure 100 is attached to the substrate 210, in some embodiments. In other embodiments, the passive components 211 are attached to the substrate 210 after the semiconductor structure 100 is attached to the substrate 210.

FIG. 2 further illustrate an underfill material 215 formed between the semiconductor structure 100 and the substrate 210. The underfill material 215 may be formed of a same or similar material using a same or similar formation method as the underfill material 133, thus details are not repeated. In some embodiments, the underfill material 215 is omitted, and the subsequently formed molding material 213 fills the gap between the semiconductor structure 100 and the substrate 210. In some embodiments, dispending the underfill material 215 may take a long time and may impact the throughput of the manufacturing process. Therefore, omitting the underfill material 215 and filling the gap between the semiconductor structure 100 and the substrate 210 using the molding material 213 may advantageously reduce the manufacturing time and improve throughput.

Still referring to FIG. 2, a dummy metal layer 141 is formed on the upper surfaces of the dies 111 and on the upper surface of the molding material 135. The dummy metal layer 141 may be formed of a suitable metal material, such as copper, gold, silver, titanium, nickel, platinum, tungsten, combinations thereof, or multilayers thereof. The dummy metal layers 141 may be formed using a suitable formation method, such as PVD, CVD, sputtering, lamination, or the like. The dummy metal layer 141 covers the upper surfaces of the dies 111 and the upper surface of the molding material 135, and may have a same dimension as the molding material 135 such that in a top view, the perimeters of the dummy metal layer 141 overlaps (e.g., completely overlaps) the perimeters of the molding material 135 of the semiconductor structure 100. The dummy metal layer 141 is electrically isolated, and is used to enhance adhesion and/or promote thermal conductivity, in some embodiments. The dummy metal layer 141 may be formed before or after the semiconductor structure 100 is attached to the substrate 210. In some embodiments, the dummy metal layer 141 is omitted. In embodiments where the dummy metal layer 141 is formed, the dummy metal layer 141 may be considered part of the semiconductor structure 100.

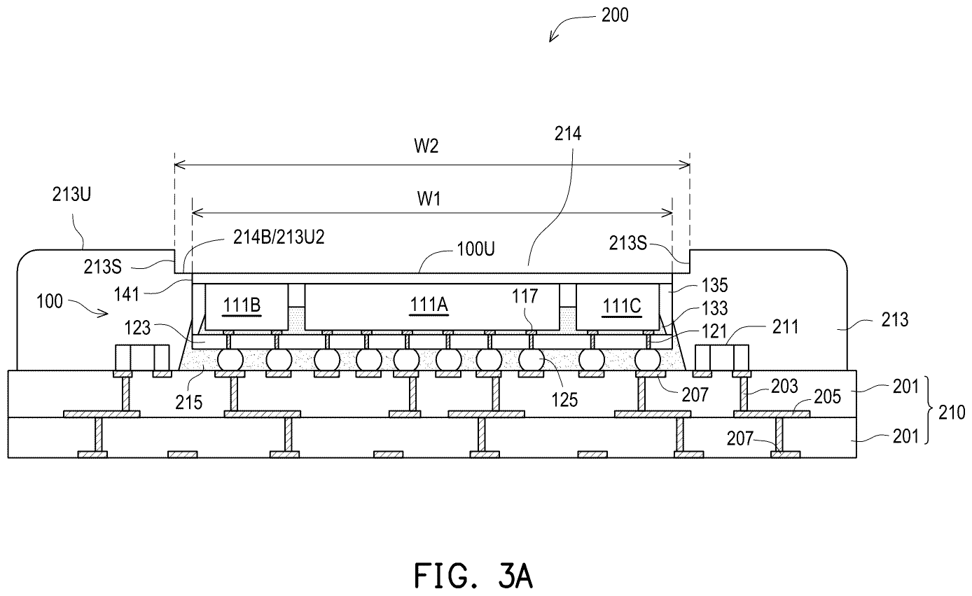

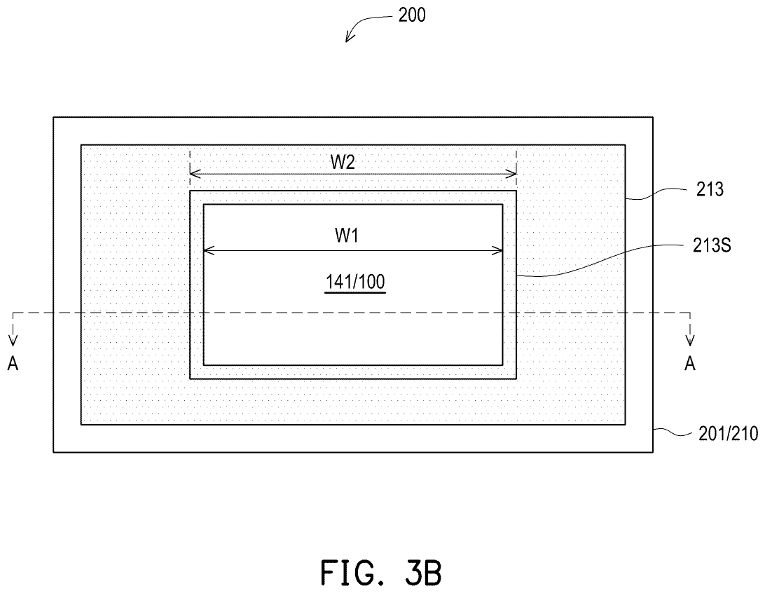

Next, in FIG. 3A, a molding material 213 (may also be referred to as an encapsulant material) is formed on the substrate 210 around the semiconductor structure 100. The passive components 211 are encapsulated in the molding material 213. In the example of FIG. 3A, the upper surface 213U of the molding material 213 is formed to extend further from the substrate 210 than the upper surface of the semiconductor structure 100. The molding material 213 may be formed of a same or similar material using a same or similar formation method as the molding material 135, thus details are not repeated.

Next, a cavity 214 (may also be referred to as a recess, or an opening) is formed in the molding material 213 over the semiconductor structure 100. In some embodiments, an etching process (e.g., an anisotropic etching process) is performed using a patterned mask layer to remove a portion of the molding material 213 disposed over the semiconductor structure 100 to form the cavity 214. The cavity 214 extends from the upper surface 213U of the molding material 213 toward the semiconductor structure 100. The upper surface 100U of the semiconductor structure 100 is exposed at a bottom 214B of the cavity 214. The upper surface 100U of the semiconductor structure 100 is the upper surface of the dummy metal layer 141 (if formed), or the upper surface of the molding material 135 if the dummy metal layer 141 is omitted. In some embodiments, the bottom 214B of the cavity 214 is formed to be level with the upper surface 100U of the semiconductor structure 100. In other embodiments, the bottom 214B of the cavity 214 is formed to extend closer to the substrate 210 than the upper surface 100U of the semiconductor structure 100. Note that a width W2 of the cavity 214, measured between opposing sidewalls 213S of the molding material 213 exposed to the cavity 214, is larger than a width W1 of the semiconductor structure 100 measured between opposing sidewalls of the semiconductor structure 100. Therefore, the bottom 214B of the cavity 214 also exposes an upper surface 213U2 of the molding material 213.

FIG. 3B illustrates a top view of the semiconductor package 200 of FIG. 3A. FIG. 3A corresponds to the cross-sectional view along cross-section A-A in FIG. 3B. In the example of FIG. 3B, the dummy metal layer 141 has a same dimension (e.g., width and length) as the molding material 135 of the semiconductor structure 100, and therefore, the perimeters (e.g., sidewalls) of the dummy metal layer 141 overlaps (e.g., completely overlaps) the perimeters (e.g., sidewalls) of the semiconductor structure 100.

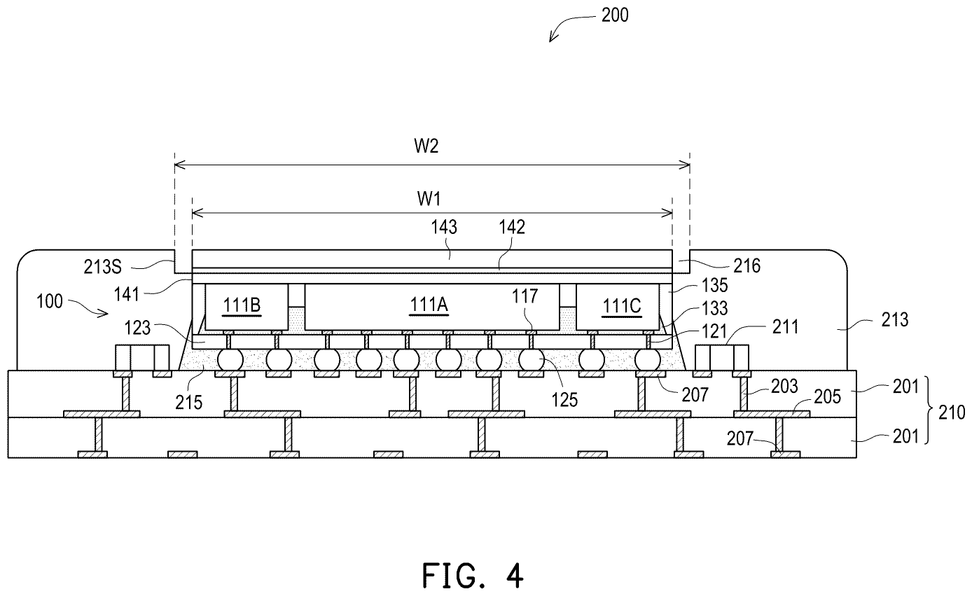

Next, in FIG. 4, a thermal interface material (TIM) 143 is formed on the dummy metal layer 141. In embodiments where the dummy metal layer 141 is omitted, the TIM 143 is formed on the dies 111 and the molding material 135. In some embodiments, the TIM 143 is a metal or metal alloy selected for its high thermal conductivity and/or conformability to the surface irregularities of the dies 111 and the subsequently attached heat spreader 230. Therefore, the TIM 143 may also be referred to as a metal TIM 143. Example materials suitable for the metal TIM 143 include indium, gallium-based alloys (such as gallium-indium-tin), and various solder alloys including tin-silver and tin-bismuth. The metal TIM 143 may be formed using direct deposition techniques, such as sputtering or evaporation, to form a thin metal layer onto the dummy metal layer 141 (if formed), or onto the backsides of the dies 111 and the molding material 135 if the dummy metal layer 141 is omitted. Alternatively, pre-formed metal TIM pads (e.g., formed using the TIM metal material(s) discussed above) may be employed, which are subsequently placed on the upper surface of the semiconductor structure 100 (e.g., on the upper surface of the dummy metal layer 141). These metal TIM pads are often secured in place using a reflow process, where the semiconductor package 200 is heated to a temperature sufficient to melt or soften the metal TIM pads, ensuring optimal contact and thermal coupling upon cooling and solidification. The reflow process ensures excellent thermal interface characteristics by enhancing surface conformity and reducing thermal resistance across the TIM layer. In some embodiments, an intermetallic compound (IMC) layer 142 is formed between the TIM 143 and the dummy metal layer 141, as illustrated in FIG. 4. For simplicity, the IMC layer 142 is not illustrated in subsequent figures, with the understanding that the IMC layer 142 may be formed.

In some embodiments, the TIM 143 is a liquid metal TIM, which is a metal or metal alloy that remains in a liquid state at a temperature between about 30° C. and about 60° C. Suitable materials for the liquid metal TIM include gallium-based alloys, such as gallium-indium or gallium-indium-tin, or allium-indium-bismuth-tin, which offer excellent thermal conductivity and wetting properties. To form the liquid metal TIM on the dummy metal layer 141, the liquid metal is carefully applied onto the dummy metal layer 141, which dummy metal layer 141 is typically formed of materials such as titanium, nickel, or gold to enhance adhesion and compatibility. The deposition process of the TIM 143 may involve techniques like syringe dispensing or screen printing to ensure precise and uniform spreading of the liquid metal across the entire surface of the dummy metal layer 141. This method ensures that the TIM 143 (e.g., liquid metal TIM) effectively fills surface irregularities, thus reducing thermal resistance and increasing heat transfer from the dies 111 to the heat spreader. The use of liquid metal as the TIM 143 provides superior thermal management capabilities due to the low viscosity and excellent surface wetting characteristics of the liquid metal.

In the example of FIG. 4, the TIM 143 covers (e.g., completely covers) the dummy metal layer 141. Sidewalls of the TIM 143 are vertically aligned with respective sidewalls of the semiconductor structure 100 (e.g., sidewalls of the dummy metal layer 141, or sidewalls of the molding material 135). The sidewalls of the TIM 143 are illustrated as straight (e.g., vertical) sidewalls as a non-limiting example. The sidewalls of the TIM 143 may be curved, in another example. In the illustrated embodiments, in a top view, the TIM 143 has a rectangular shape that overlaps (e.g., completely overlap) the rectangular shape of the semiconductor structure 100, in some embodiments. Note that in FIG. 4, the TIM 143 fills the center portion of the cavity 214 in the molding material 213, but leaves the peripheral portion of the cavity 214 open (e.g., unfilled). Therefore, after the TIM 143 is formed, there is a gap 216 between sidewalls of the TIM 143 and sidewalls 213S of the molding material 213. The gap 216 corresponds to the peripheral portion of the cavity 214. In a top view, the gap 216 may be a rectangular shaped trench in the molding material 213 and around the TIM 143. The gap 216 is formed due to the width W2 of the cavity 214 being larger than the width W1 of the TIM 143, in some embodiments.

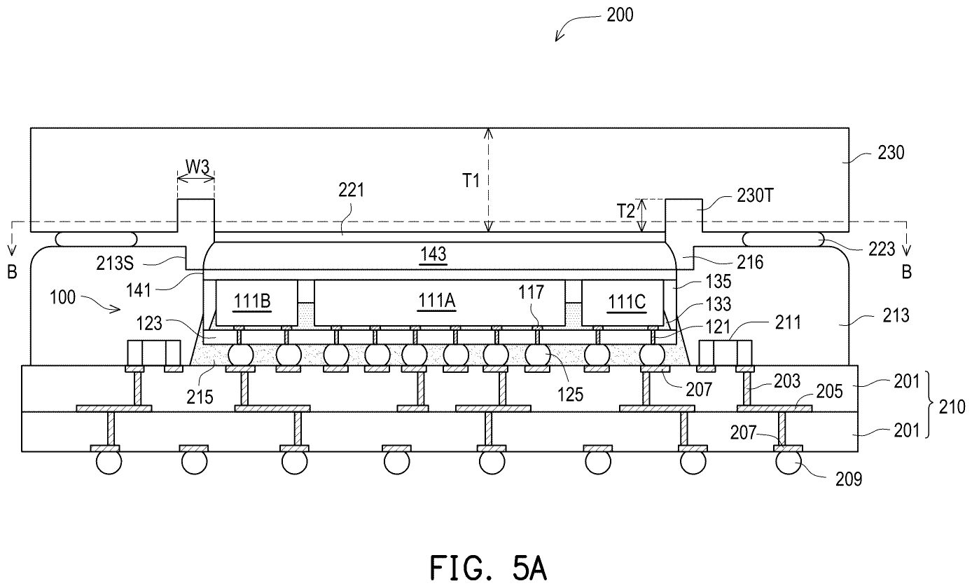

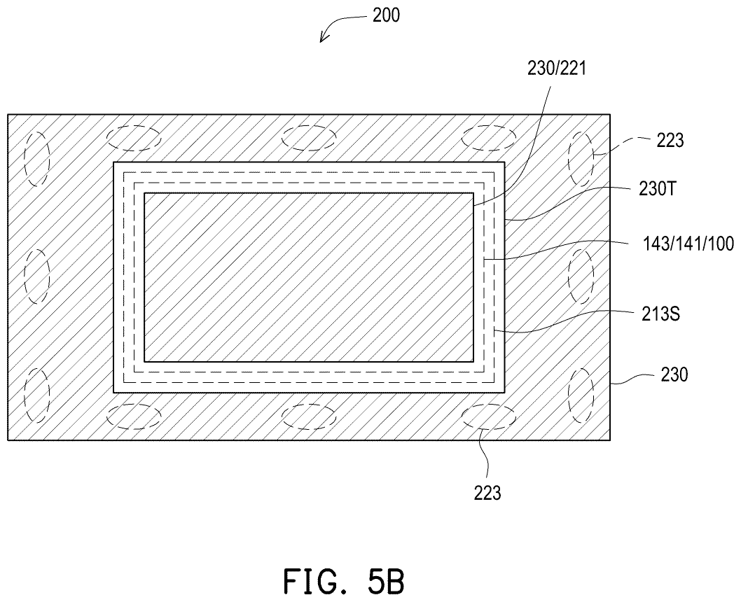

Next, in FIG. 5A, a heat spreader 230 (may also be referred to as a lid) is attached to the upper surface of the molding material 213 by an adhesive material 223 (e.g., a glue). A lower surface of a middle portion of the heat spreader 230 facing the TIM 143 is thermally coupled to the TIM 143. In the example of FIG. 5A, a dummy metal layer 221 same as or similar to the dummy metal layer 141 is formed between the TIM 143 and the heat spreader 230, in order to facilitate heat transfer and/or enhance adhesion between the TIM 143 and the heat spreader 230. In the example of FIG. 5A, sidewalls of the dummy metal layer 221 are aligned with respective sidewalls of a trench 230T at the lower surface of the heat spreader 230. In addition, in FIG. 5A, sidewalls of the TIM 143 are curved, with the upper surface of the TIM 143 having a same width with the dummy metal layer 221, and with the lower surface of the TIM 143 having a same width as the dummy metal layer 141. In other words, the width of the TIM 143 in FIG. 5A increases continuously along a depth direction (e.g., vertical direction of FIG. 5A) of the TIM 143 toward the semiconductor structure 100. Although not illustrated, an IMC layer may be formed between the TIM 143 and the dummy metal layer 221. In other embodiments, the dummy metal layer 221 is omitted, and the heat spreader 230 is in direct contact with (e.g., physically contacts) the TIM 143.

In some embodiments, after the adhesive material 223 is dispensed, e.g., between the heat spreader 230 and the molding material 213, a heating process is performed to cure the adhesive material 223. The heating process may also promote bonding between the TIM 143 and the dummy metal layer 141 (or 221). For example, the material (e.g., indium) of the TIM 143 may interact with the material (e.g., gold) of the dummy metal layer 141 (or 221) to form a eutectic alloy that enhances metallurgical bonding through improved adhesion and mechanical stability compared to non-eutectic compositions. The formation of the eutectic bond helps to ensure that the TIM 143 remains securely bonded under thermal cycling conditions commonly experienced in semiconductor applications. This strong metallurgical connection can significantly reduce thermal and mechanical resistance, enhancing thermal performance and reliability of the package.

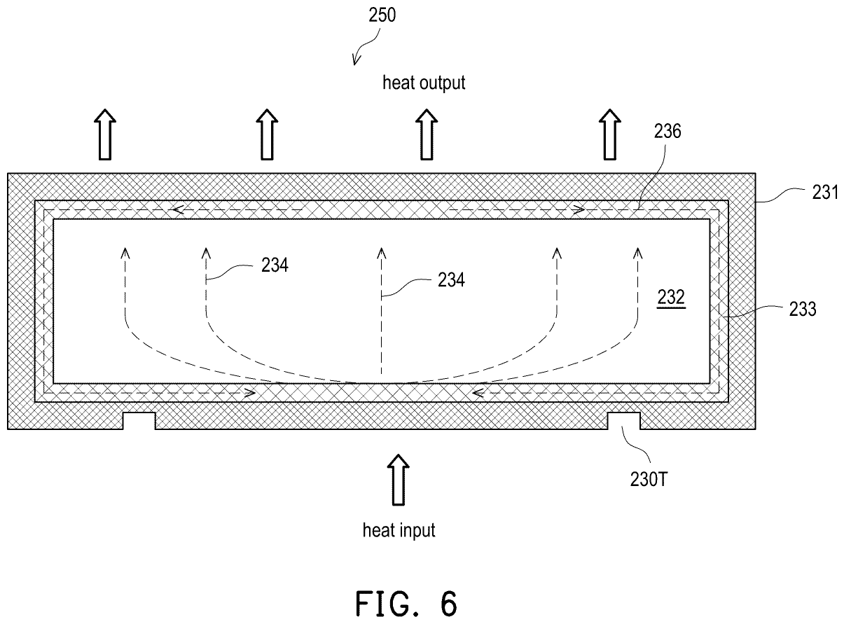

In some embodiments, the heat spreader 230 is a solid piece of material with a trench 230T formed at a lower surface of the solid piece of material facing the TIM 143. The solid piece of material is a suitable material with excellent heat conductivity, such as copper, aluminum, a copper alloy (e.g., copper-tungsten or copper-molybdenum), an aluminum alloy, graphite, diamond or diamond composites, ceramics, a carbon-based material (e.g., carbon nanotubes or carbon fiber composites), or the like. In other embodiments, the heat spreader 230 is a vapor chamber (VC) with a trench 230T formed at a lower surface of the vapor chamber facing the TIM 143. Details of the vapor chamber is discussed hereinafter with reference to FIG. 6.

Notably, in the example of FIG. 5A, a trench 230T (may also be referred to as a recess) is formed at a lower surface of the heat spreader 230 facing the TIM 143. In particular, after the heat spreader 230 is attached to the TIM 143, the trench 230T is disposed over (e.g., directly over) the gap 216. In the illustrated embodiment, the sidewall 213S of the molding material 213 and the sidewall of the TIM 143 are disposed within the laterally extents (e.g., between the sidewalls) of the trench 230T. More details are illustrated in FIG. 5B.

FIG. 5B illustrates a cross-sectional view of the semiconductor package 200 in FIG. 5A along cross-section B-B. For simplicity, not all features of the semiconductor package 200 are illustrated. In addition, to illustrate the relative locations of different features, some features not visible in the cross-section B-B are illustrated in phantom in FIG. 5B.

In the cross-sectional view of FIG. 5B, the trench 230T in the heat spreader 230 has a rectangular annular shape. The sidewalls 213S of the molding material 213 facing the gap 216 are illustrated as a rectangular shape in dashed lines. The sidewalls of the TIM 143 are illustrated as another rectangular shape in dashed lines. As discussed above, the TIM 143, the dummy metal layers 141/221, and the semiconductor structure 100 have a same dimension in a top view, thus their sidewalls completely overlap in the top view, in some embodiments. Notably, in the example of FIG. 5B, the sidewalls of the semiconductor structure 100 and the sidewalls 213S of the molding material 213 are disposed within the rectangular annular shape of the trench 230T.

FIG. 5B further illustrates the adhesive material 223 in dashed lines. The adhesive material 223 include discrete portions that are spaced apart from each other. In some embodiments, the TIM 143 is attached to the dummy metal layer 141 through a bonding process (e.g., a reflow process), and a flux is used in the bonding process to, e.g., remove oxide from the surfaces being bonded together. During the bonding process, the flux evaporates due to the heat of the bonding process. The gap 216 between the TIM 143 and the molding material 213 and the gaps between the discrete portions of the adhesive material 223 allow the gas from the evaporation of the flux to escape.

FIG. 6 illustrates a cross-sectional view of a vapor chamber (VC) 250, in accordance with an embodiment. The vapor chamber 250 may be used as the heat spreader 230 in FIGS. 5A and 5B. The vapor chamber 250 comprises a sealed container 231 (may also be referred to as a shell, or a housing) that houses an internal chamber 232 (e.g., an enclose space). In various embodiments, the sealed container 231 may be fabricated from a thermally conductive material(s) such as copper, aluminum, or other suitable metals or alloys that facilitate efficient heat transfer.

The vapor chamber 250 includes a wick structure 233 positioned along the inner walls of the sealed container 231. In an embodiment, the wick structure 233 extends throughout the internal chamber 232 to facilitate the movement of condensed liquid. The vapor chamber 250 further comprises a working fluid (not shown) contained within the internal chamber 232, which undergoes phase transitions during operation.

As illustrated in FIG. 6, the vapor chamber 250 operates by receiving heat input at the bottom surface, as indicated by the upward arrow labeled “heat input.” When heat enters the vapor chamber 250, the working fluid at the heat input location evaporates, creating vapor that moves through the internal chamber 232. The movement paths of the vapor are represented by the dotted lines 234 in FIG. 6. The vapor travels through the internal chamber 232 and eventually reaches cooler regions (e.g., the top surface of the vapor chamber 250). In these cooler regions, the vapor condenses back into liquid form. This condensation process releases the absorbed heat, which is then dissipated through the top surface of the vapor chamber 250 as heat output, represented by the upward arrows labeled “heat output.” In various embodiments, the condensed liquid returns to the heat input location through the wick structure 233 via capillary action. The dashed lines 236 in FIG. 6 illustrate the return paths of the condensed liquid. The wick structure 233 creates capillary pressure that draws the condensed liquid back toward the heat source, completing the thermal cycle. This continuous evaporation-condensation cycle enables effective heat transfer from the heat input location to the heat output locations.

The design of the vapor chamber 250 allows for efficient spreading of heat across a wide area, converting a concentrated heat source into a distributed heat output. This characteristic makes the vapor chamber 250 particularly effective for applications where uniform heat distribution is advantageous. The evaporation-condensation cycle within the vapor chamber 250 enables high thermal conductivity, exceeding that of solid metal heat spreaders of comparable dimensions.

In the example of FIG. 6, the vapor chamber 250 includes the trench 230T formed at the bottom surface of the vapor chamber 250. The location of the trench 230T is chosen such that when the vapor chamber 250 is attached to the TIM 143, the trench 230T is directly over the gap 216, as illustrated in FIG. 5A and discussed above.

Referring back to FIG. 5A, the trench 230T at the lower surface of the heat spreader 230 may be formed by, e.g., machining, laser drilling, or the like. A width W3 of the trench 230T may be equal to or larger than 100 μm. A depth T2 of the trench 230T may be equal to or larger than 100 μm, or equal to or larger than 300 μm, such as being about 500 μm. In some embodiments, the depth T2 of the trench 230T is between about 5% and about 60%, such as between about 15% and about 50%, of a thickness T1 of the heat spreader 230. In some embodiments, the dimension (e.g., W2, T2) of the trench 230T is chosen based on the characteristics (e.g., cohesive force) of the molten metal material of the TIM 143, and based on ability of the trench 230T to trap the molten metal material of the TIM 143 during manufacturing and/or operation of the semiconductor package 200. More details are discussed hereinafter.

Next, external connectors 209, which may be solder balls, copper pillars, or the like, are formed on the conductive pads 207 at the lower surface of the substrate 210. Therefore, the semiconductor structure 100, the passive components 211, and the external connectors 209 are electrically interconnected through the conductive features of the substrate 210.

As more and more dies are integrated into semiconductor packages to achieve higher level of integration and higher performance, heat dissipation of the semiconductor packages becomes a challenge. If left un-addressed, inefficient heat dissipation limits the integration density achievable and/or performance of the semiconductor packages. Inefficient heat dissipation may cause other issues, such as warpage of the semiconductor package due to mismatch of the coefficients of thermal expansion (CTEs) of the different materials in the semiconductor packages. Another issue is the pump-out of the TIM material, which refers to the issue when the TIM material is squeezed out of its place due to thermal expansion of the structures above and below the TIM material.

The presently disclosed semiconductor packages achieve improved heat dissipation efficiency, and prevents or alleviates the various issues discussed above. For example, due to the ability of the TIM 143 (e.g., a liquid metal TIM, or a metal TIM with low melting point that softens when heated) to fill surface irregularities, reduced thermal resistance and increased heat transfer efficiency from the dies 111 to the heat spreader 230 are achieved. As another example, the eutectic alloy formed at the interface of the TIM 143 and the dummy metal layer 141 (or 221) enhances metallurgical bonding through improved adhesion and mechanical stability. This strong metallurgical connection can significantly reduce thermal and mechanical resistance, enhancing thermal performance and reliability of the package. In addition, the formation of the eutectic bond, together with the cavity 214 (which limits the movement of the TIM 143), ensure that the TIM 143 remains securely bonded and stays in the cavity 214 under thermal cycling conditions, thus avoiding or alleviating the pump-out issue. The gap 216 between the TIM 143 and the molding material 213 is useful for trapping the molten metal material of the TIM 143 during manufacturing or operation of the semiconductor package. For example, during the formation process for the external connectors 209, a heating process (e.g., a ball bonding process) may be performed. The temperature of the heating processing may reach over 200° C., which may melt the TIM 143. The gap 216 is able to trap the molten metal material of the TIM 143, thus preventing the molten metal material from causing, e.g., electrical short or other problems. Since the semiconductor package may be flipped upside-down, the trench 230T is formed in the heat spreader 230 to trap the molten metal material of the TIM 143 in such an upside-down position. Another advantage of having the gap 216 is to allow the gas from the evaporation of the flux to escape, as discussed above.

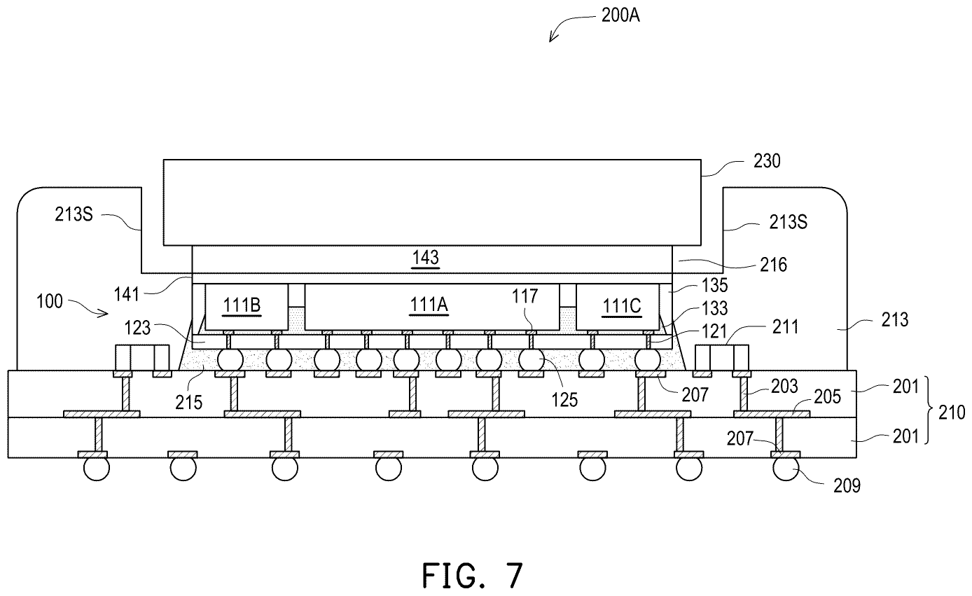

FIG. 7 illustrates a cross-sectional view of a semiconductor package 200A, in accordance with an embodiment. The semiconductor package 200A is similar to the semiconductor package 200, but the heat spreader 230 is disposed within the lateral extents of the cavity 214 in the molding material 213. In other words, the heat spreader 230 is disposed between the opposing sidewalls 213S of the molding material 213 exposed to the cavity 214. In the example of FIG. 7, the lower surface of the heat spreader 230 is bonded to the TIM 143 and is in direct contact with the TIM 143. In some embodiments, a dummy metal layer 221 (see, e.g., FIG. 5A) is formed between the heat spreader 230 and the TIM 143. The heat spreader 230 is a solid piece of a suitable material, such as those discussed above, in some embodiments. In some embodiments, the heat spreader 230 is a vapor chamber same as or similar to the vapor chamber 250.

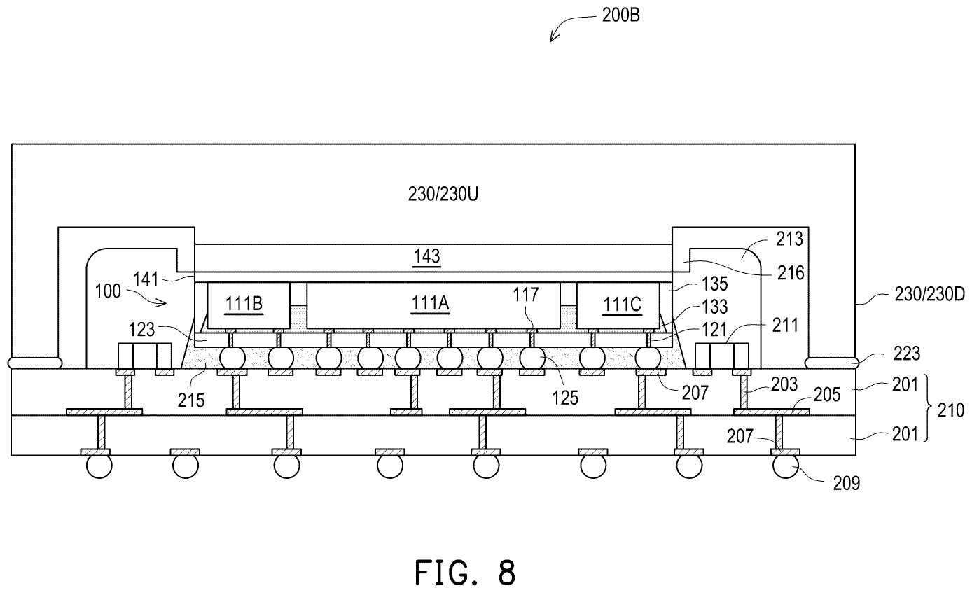

FIG. 8 illustrates a cross-sectional view of a semiconductor package 200B, in accordance with another embodiment. The semiconductor package 200B is similar to the semiconductor package 200A, but the heat spreader 230 includes a top portion 230U that is attached to (e.g., in contact with) the TIM 143, and includes downward-extending portions 230D that extend from the top portion 230U toward the substrate 210. The adhesive material 223 is formed between the downward-extending portions 230D and the substrate 210. The heat spreader 230 in FIG. 8 may be formed of a solid piece of a suitable material, or may be, e.g., a vapor chamber. Notably, in FIG. 8, the middle region of the top portion 230D of the heat spreader 230 is thicker than the peripheral region of the top portion 230D, and the middle region of the top portion 230U extends into the cavity 214 to be in contact with the TIM 143.

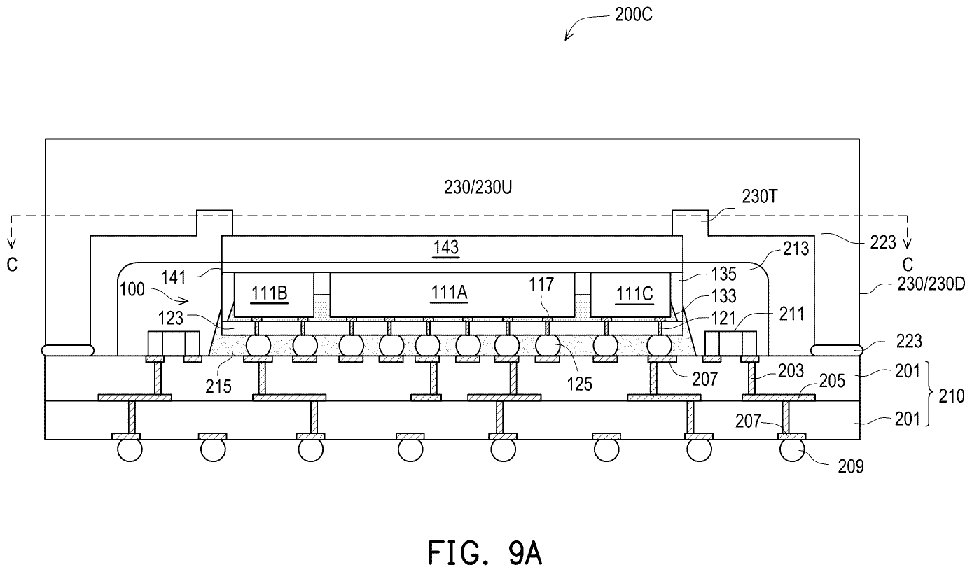

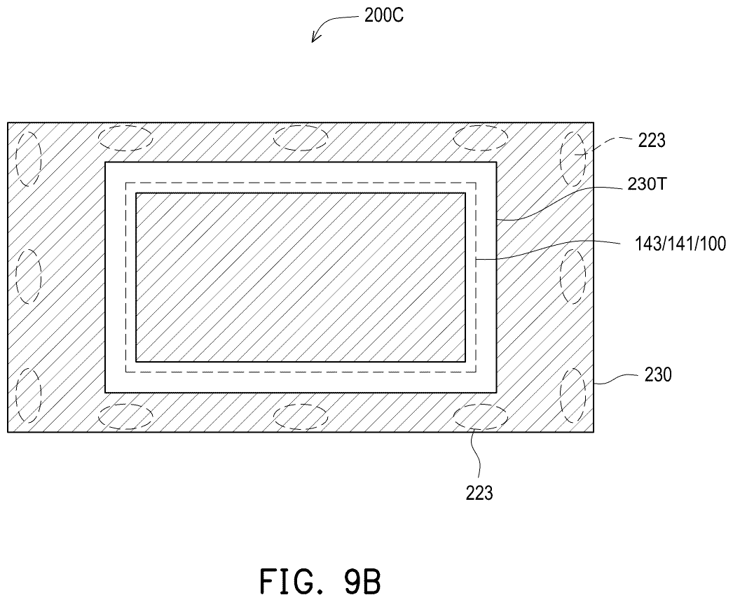

FIGS. 9A and 9B illustrate various views of a semiconductor package 200C, in accordance with another embodiment. The semiconductor package 200C in FIG. 9A is similar to the semiconductor package 200B, but the upper surface of the molding material 213 is substantially level with the upper surface of dummy metal layer 141. In some embodiments, after the molding material 213 is formed on the substrate 210 around the semiconductor structure 100, a planarization process, such as CMP, is performed to achieve a coplanar upper surface between the molding material 213 and the semiconductor structure 100. In other words, the etching process to form the cavity 214 in the molding material 213 is omitted for the semiconductor package 200C, in some embodiments. In addition, the trench 230T is formed in the lower surface of the heat spreader 230 over (e.g., directly over) the sidewall of the TIM 143. The heat spreader 230 in FIG. 9A may be formed of a solid piece of a suitable material, or may be, e.g., a vapor chamber same as or similar to the vapor chamber 250.

FIG. 9B illustrates a cross-sectional view of the semiconductor package 200C in FIG. 9A along cross-section C-C. For simplicity, not all features of the semiconductor package 200C are illustrated. In addition, to illustrate the relative locations of different features, some features not visible in the cross-section C-C are illustrated in phantom in FIG. 9B.

In the cross-sectional view of FIG. 9B, the trench 230T in the heat spreader 230 has a rectangular annular shape. The sidewalls of the TIM 143 are illustrated as a rectangular shape in dashed lines. Note that in the illustrated embodiments, the sidewalls of the TIM 143 are also the sidewalls of the semiconductor structure 100 (or sidewalls of the dummy metal layer 141). In the cross-sectional view of FIG. 9B, the sidewalls of the TIM 143 are disposed within the rectangular annular shape of the trench 230T.

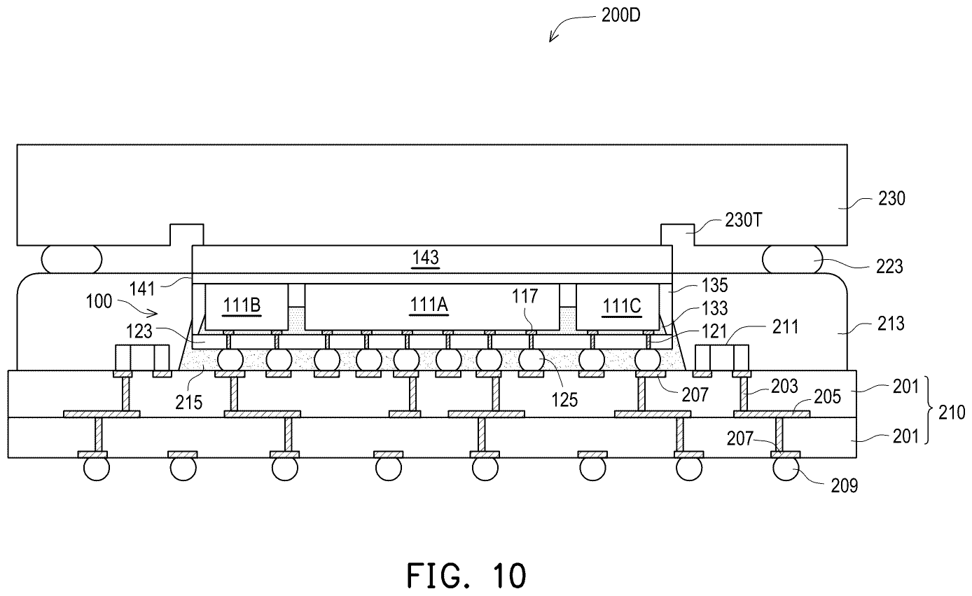

FIG. 10 illustrates a cross-sectional view of a semiconductor package 200D, in accordance with another embodiment. The semiconductor package 200D in FIG. 10 is similar to the semiconductor package 200C, but the heat spreader 230 does not have the downward-extending portions 230D. In addition, the adhesive material 223 is formed between the lower surface of the heat spreader 230 and the upper surface of the molding material 213. The heat spreader 230 in FIG. 10 may be formed of a solid piece of a suitable material, or may be, e.g., a vapor chamber same as or similar to the vapor chamber 250.

In some embodiments, the TIM 143 in the semiconductor packages 200, 200A, and 200B are formed of a low-temperature metal TIM, which may have a melting temperature lower than 300° C. Due to high probability of the TIM 143 (e.g., a low-temperature metal TIM) being melted, the cavity 214 (and the gap 216) is formed in the molding material 213 to trap the molten metal material of the metal TIM. In some embodiments, the TIM 143 in the semiconductor packages 200C and 200D are formed of a high-temperature metal TIM, which may have a melting temperature higher than 300° C. Due to low probability of the TIM 143 (e.g., a high-temperature metal TIM) being melted, the cavity 214 (and the gap 216) is not formed in the molding material 213.

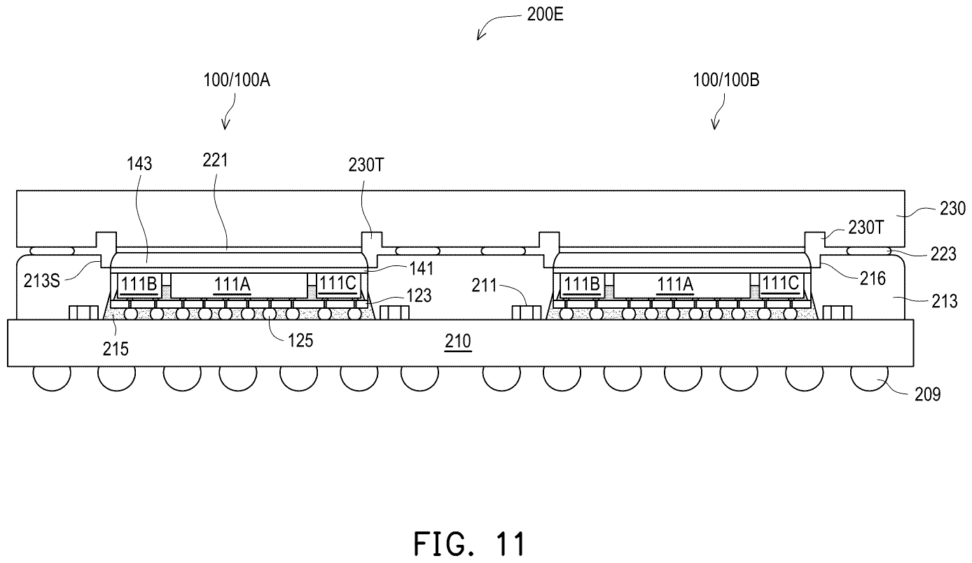

FIG. 11 illustrates a cross-sectional view of a semiconductor package 200E, in accordance with yet another embodiment. The semiconductor package 200E in FIG. 11 is similar to the semiconductor package 200 in FIG. 5A, but with multiple semiconductor structures 100 (e.g., 100A and 100B) embedded in the molding material 213. A cavity 214 is formed in the molding material 213 for each of the semiconductor structures 100, and a gap 216 is formed between the TIM 143 of each semiconductor structure 100 and a respective sidewall 213S of the molding material 213. In addition, a trench 230T is formed in the heat spreader 230 over the gap 216 around each semiconductor structure 100. The heat spreader 230 in FIG. 11 may be formed of a solid piece of a suitable material, or may be, e.g., a vapor chamber same as or similar to the vapor chamber 250.

Advantages are achieved by the disclosed embodiments. The presently disclosed semiconductor packages achieve improved heat dissipation efficiency, thus allowing for higher integration density and/or higher device performance. In addition, warpage of the semiconductor packages is reduced, and the pump-out issue for the TIM 143 is avoided. The gap 216 in the molding material 213 and the trench 230T in the heat spreader 230 can trap molten metal material of the TIM 143, thus avoiding electrical short. The gap 216 and the gaps between the discrete portions of the adhesive material 223 allow the gas from the evaporation of flux to escape. The molding material 213 encapsulates and protects the passive components 211 from potential damage or electrical short (e.g., caused by molten metal material of the TIM).

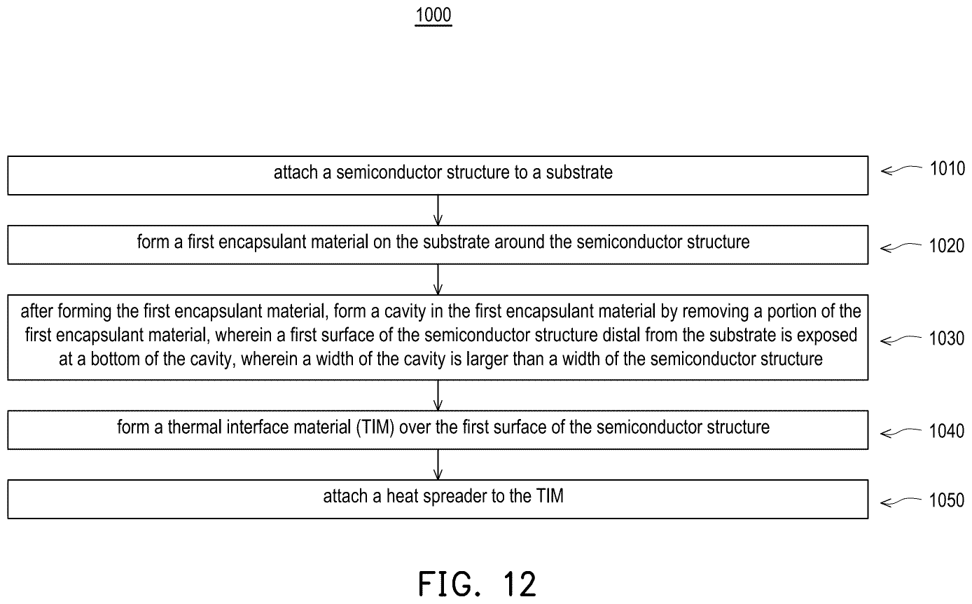

FIG. 12 illustrates a flow chart of a method 1000 of forming a semiconductor package, in some embodiments. It should be understood that the embodiment method shown in FIG. 12 is merely an example of many possible embodiment methods. One of ordinary skill in the art would recognize many variations, alternatives, and modifications. For example, various steps as illustrated in FIG. 12 may be added, removed, replaced, rearranged and repeated.

Referring to FIG. 12, at block 1010, a semiconductor structure is attached to a substrate. At block 1020, a first encapsulant material is formed on the substrate around the semiconductor structure. At block 1030, after forming the first encapsulant material, a cavity is formed in the first encapsulant material by removing a portion of the first encapsulant material, wherein a first surface of the semiconductor structure distal from the substrate is exposed at a bottom of the cavity, wherein a width of the cavity is larger than a width of the semiconductor structure. At block 1040, a thermal interface material (TIM) is formed over the first surface of the semiconductor structure. At block 1050, a heat spreader is attached to the TIM.

In accordance with an embodiment, a semiconductor package includes: a substrate and a semiconductor structure attached to the substrate, wherein the semiconductor structure comprises: an interposer; a die attached to a first side of the interposer distal from the substrate; a first encapsulant material on the first side of the interposer around the die; and conductive bumps at a second side of the interposer facing the substrate. The semiconductor package further includes a second encapsulant material on the substrate around the semiconductor structure, wherein there is a cavity in the second encapsulant material over the semiconductor structure, wherein the cavity extends from a first surface of the second encapsulant material distal from the substrate toward the semiconductor structure, wherein a first side of the semiconductor structure distal from the substrate is exposed at a bottom of the cavity; a thermal interface material (TIM) in the cavity and attached to the first side of the semiconductor structure; and a heat spreader over and attached to the TIM. In an embodiment, the first surface of the second encapsulant material extends further from the substrate than the first side of the semiconductor structure, wherein the bottom of the cavity is between the first surface of the second encapsulant material and a second opposing surface of the second encapsulant material. In an embodiment, the bottom of the cavity is level with, or is closer to the substrate than, the first side of the semiconductor structure. In an embodiment, there is a gap between the TIM and a sidewall of the second encapsulant material exposed to the cavity. In an embodiment, there is a recess at a first side of the heat spreader facing the substrate, wherein the recess is directly over the gap. In an embodiment, in a top view, the recess has a rectangular annular shape, the TIM has a first rectangular shape, and the sidewall of the second encapsulant material has a second rectangular shape, wherein in the top view, first perimeters of the first rectangular shape and second perimeters of the second rectangular shape are disposed within the rectangular annular shape. In an embodiment, a depth of the recess, measured along a depth direction of the TIM, is between about 5% and about 60% of a thickness of the heat spreader measured along the depth direction of the TIM. In an embodiment, a first portion of the heat spreader extends into the cavity, wherein the first portion of the heat spreader is attached to the TIM and is spaced apart from the sidewall of the second encapsulant material. In an embodiment, a second portion of the heat spreader extends above the first surface of the second encapsulant material and beyond opposing sidewalls of the cavity. In an embodiment, the semiconductor structure further comprises a dummy metal layer attached to a backside of the die, wherein the TIM is attached to the dummy metal layer. In an embodiment, the semiconductor package further comprises an intermetallic compound (IMC) layer between the TIM and the dummy metal layer. In an embodiment, the semiconductor package further comprises another dummy metal layer disposed between the TIM and the heat spreader.

In accordance with an embodiment, a semiconductor package includes: a substrate; a first encapsulant material on the substrate; and a semiconductor structure embedded in the first encapsulant material, wherein the semiconductor structure comprises: an interposer; a die attached to a first side of the interposer distal from the substrate; a second encapsulant material on the first side of the interposer around the die; and conductive bumps at a second side of the interposer facing the substrate. The semiconductor package further includes: a thermal interface material (TIM) over a first side of the semiconductor structure distal from the substrate, wherein the first side of the semiconductor structure is exposed by the first encapsulant material; and a heat spreader over and attached to the TIM, wherein a lower surface of the heat spreader facing the semiconductor structure has a recess proximate to a sidewall of the TIM. In an embodiment, the semiconductor structure further comprises a dummy metal layer attached to a backside of the die facing away from the interposer, wherein the TIM contacts and extends along the dummy metal layer. In an embodiment, there is a cavity in the first encapsulant material, and the TIM is disposed in the cavity, wherein the TIM is spaced apart from sidewalls of the first encapsulant material exposed to the cavity. In an embodiment, the first side of the semiconductor structure is at a same distance from the substrate as a first side of the first encapsulant material distal from the substrate.

In accordance with an embodiment, a method of forming a semiconductor package includes: attaching a semiconductor structure to a substrate; forming a first encapsulant material on the substrate around the semiconductor structure; after forming the first encapsulant material, forming a cavity in the first encapsulant material by removing a portion of the first encapsulant material, wherein a first surface of the semiconductor structure distal from the substrate is exposed at a bottom of the cavity, wherein a width of the cavity is larger than a width of the semiconductor structure; forming a thermal interface material (TIM) over the first surface of the semiconductor structure; and attaching a heat spreader to the TIM. In an embodiment, the semiconductor structure comprises: an interposer; a die attached to a first side of the interposer; a second encapsulant material on the first side of the interposer around the die; and conductive bumps at a second opposing side of the interposer, wherein attaching the semiconductor structure comprises bonding the conductive bumps to respective contact pads of the substrate. In an embodiment, the width of the cavity is larger than a width of the TIM, wherein after forming the TIM, a gap is formed between the TIM and a sidewall of the first encapsulant material exposed to the cavity. In an embodiment, the method further comprises, before forming the TIM, forming a dummy metal layer along a backside of the die distal from the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a substrate;
a semiconductor structure attached to the substrate, wherein the semiconductor structure comprises:
an interposer;
a die attached to a first side of the interposer distal from the substrate;
a first encapsulant material on the first side of the interposer around the die; and
conductive bumps at a second side of the interposer facing the substrate;
a second encapsulant material on the substrate around the semiconductor structure, wherein there is a cavity in the second encapsulant material over the semiconductor structure, wherein the cavity extends from a first surface of the second encapsulant material distal from the substrate toward the semiconductor structure, wherein a first side of the semiconductor structure distal from the substrate is exposed at a bottom of the cavity;
a thermal interface material (TIM) in the cavity and attached to the first side of the semiconductor structure; and
a heat spreader over and attached to the TIM.

2. The semiconductor package of claim 1, wherein the first surface of the second encapsulant material extends further from the substrate than the first side of the semiconductor structure, wherein the bottom of the cavity is between the first surface of the second encapsulant material and a second opposing surface of the second encapsulant material.

3. The semiconductor package of claim 2, wherein the bottom of the cavity is level with, or is closer to the substrate than, the first side of the semiconductor structure.

4. The semiconductor package of claim 2, wherein there is a gap between the TIM and a sidewall of the second encapsulant material exposed to the cavity.

5. The semiconductor package of claim 4, wherein there is a recess at a first side of the heat spreader facing the substrate, wherein the recess is directly over the gap.

6. The semiconductor package of claim 5, wherein in a top view, the recess has a rectangular annular shape, the TIM has a first rectangular shape, and the sidewall of the second encapsulant material has a second rectangular shape, wherein in the top view, first perimeters of the first rectangular shape and second perimeters of the second rectangular shape are disposed within the rectangular annular shape.

7. The semiconductor package of claim 6, wherein a depth of the recess, measured along a depth direction of the TIM, is between about 5% and about 60% of a thickness of the heat spreader measured along the depth direction of the TIM.

8. The semiconductor package of claim 4, wherein a first portion of the heat spreader extends into the cavity, wherein the first portion of the heat spreader is attached to the TIM and is spaced apart from the sidewall of the second encapsulant material.

9. The semiconductor package of claim 8, wherein a second portion of the heat spreader extends above the first surface of the second encapsulant material and beyond opposing sidewalls of the cavity.

10. The semiconductor package of claim 4, wherein the semiconductor structure further comprises a dummy metal layer attached to a backside of the die, wherein the TIM is attached to the dummy metal layer.

11. The semiconductor package of claim 10, further comprising an intermetallic compound (IMC) layer between the TIM and the dummy metal layer.

12. The semiconductor package of claim 10, further comprising another dummy metal layer disposed between the TIM and the heat spreader.

13. A semiconductor package comprising:
a substrate;
a first encapsulant material on the substrate;
a semiconductor structure embedded in the first encapsulant material, wherein the semiconductor structure comprises:
an interposer;
a die attached to a first side of the interposer distal from the substrate;
a second encapsulant material on the first side of the interposer around the die; and
conductive bumps at a second side of the interposer facing the substrate;
a thermal interface material (TIM) over a first side of the semiconductor structure distal from the substrate, wherein the first side of the semiconductor structure is exposed by the first encapsulant material; and
a heat spreader over and attached to the TIM, wherein a lower surface of the heat spreader facing the semiconductor structure has a recess proximate to a sidewall of the TIM.

14. The semiconductor package of claim 13, wherein the semiconductor structure further comprises a dummy metal layer attached to a backside of the die facing away from the interposer, wherein the TIM contacts and extends along the dummy metal layer.

15. The semiconductor package of claim 13, wherein there is a cavity in the first encapsulant material, and the TIM is disposed in the cavity, wherein the TIM is spaced apart from sidewalls of the first encapsulant material exposed to the cavity.

16. The semiconductor package of claim 13, wherein the first side of the semiconductor structure is at a same distance from the substrate as a first side of the first encapsulant material distal from the substrate.

17. A method of forming a semiconductor package, the method comprising:
attaching a semiconductor structure to a substrate;
forming a first encapsulant material on the substrate around the semiconductor structure;
after forming the first encapsulant material, forming a cavity in the first encapsulant material by removing a portion of the first encapsulant material, wherein a first surface of the semiconductor structure distal from the substrate is exposed at a bottom of the cavity, wherein a width of the cavity is larger than a width of the semiconductor structure;
forming a thermal interface material (TIM) over the first surface of the semiconductor structure; and
attaching a heat spreader to the TIM.

18. The method of claim 17, wherein the semiconductor structure comprises:
an interposer;
a die attached to a first side of the interposer;
a second encapsulant material on the first side of the interposer around the die; and
conductive bumps at a second opposing side of the interposer, wherein attaching the semiconductor structure comprises bonding the conductive bumps to respective contact pads of the substrate.

19. The method of claim 17, wherein the width of the cavity is larger than a width of the TIM, wherein after forming the TIM, a gap is formed between the TIM and a sidewall of the first encapsulant material exposed to the cavity.

20. The method of claim 17, further comprising, before forming the TIM, forming a dummy metal layer along a backside of the die distal from the substrate.
